(19) United States
(12) Patent Application Publication
(10) Pub. No.: US 2020/0355732 A1
(43) Pub. Date: Nov. 12, 2020

(54) IMPEDANCE MEASUREMENT CIRCUIT

(71) Applicant: Analog Devices International Unlimited Company, Limerick (IE)

(72) Inventor: Andreas KOCH, Herderstrasse 16 (DE)

(73) Assignee: Analog Devices International Unlimited Company, Limerick (IE)

(21) Appl. No.: 16/407,103

(22) Filed: May 8, 2019

(51) Int. Cl. G01R 27/26; H03M 1/46

(52) U.S. Cl. CPC G01R 27/26; H03M 1/466

(57) ABSTRACT

There is disclosed in one example a circuit for measuring impedance, including: a current mirror including a first current path and a second current path; a sensor having a terminal electrically coupled to the first current path of the current mirror circuit; a charge collector electrically coupled to the second current path of the current mirror; and an analog-to-digital converter to output a digital value of charge on the charge collector over a known time, wherein the digital value corresponds to an impedance of the sensor.

### TECHNICAL FIELD OF THE DISCLOSURE

This disclosure relates in general to the field of signal conditioning, and more particularly, though not exclusively, to a system and method for providing an impedance measurement circuit.

### BACKGROUND

Sensors, such as electrochemical sensors, can measure parameters such as voltage (or other values) as part of their chemical detection. Changes in internal impedances over time may represent degradation of the materials, which can reduce accuracy of the sensor.

### BRIEF DESCRIPTION OF THE DRAWINGS

FIG. 1 is a schematic diagram of an example impedance measurement circuit, according to the teachings of the present specification.

FIGS. 2A-2M are schematic diagrams illustrating operation of the example impedance measurement circuit of FIG. 1, according to the teachings of the present specification.

FIGS. 3A-3K are graphical representations of electrical response for operating the impedance measurement circuit of FIG. 1, according to the teachings of the present specification.

FIG. 4 is a schematic block diagram illustrating an example sensor system that incorporates the impedance measurement circuit of FIG. 1, according to the teachings of the present specification.

FIG. 5 is a process flow diagram for calibrating the impedance measurement circuit of FIG. 1, according to the teachings of the present specification.

FIGS. 6A and 6B are a process flow diagram illustrating performing impedance measurement using the example circuit of FIG. 1, according to the teachings of the present specification.

FIG. 7 is a block diagram of a blood glucose monitor, illustrating an application of the teachings of the present specification.

FIG. 8 is a block diagram of a smart watch, illustrating a further application of the teachings of the present specification.

### SUMMARY

In an example, there is disclosed a circuit for measuring an impedance connected to its input, comprising: a current mirror comprising a first current path and a second current path; a sensor having a terminal electrically coupled to the first current path of the current mirror circuit; a charge collector electrically coupled to the second current path of the current mirror; and an analog-to-digital converter to output a digital value of charge on the charge collector over a known time, wherein the digital value corresponds to an impedance of the sensor.

### EMBODIMENTS OF THE DISCLOSURE

Measuring impedance is an electrical function that can be used in many types of transducers and circuits. For example, impedance or changes in impedance can be used to detect the presence or absence of certain chemicals in a medium, the health of a conductor (e.g., as the conductor decays or oxidizes, its resistivity increases), the operating state of a circuit, the absence or presence of a signal, and many other applications.

At a basic level, impedance can be derived from fundamental laws, such as V=IR (Ohm's Law). For example, by applying a known voltage to a circuit and measuring the current drawn by the circuit, the impedance of the circuit can be calculated using R=V/I. Although these laws are fundamental, in practice they are not always easy. In particular, when the impedance is not merely a pure resistance, but also has a reactive (e.g., capacitive or inductive) component, then a complex impedance may need to be measured. This involves measuring not only the magnitude of the resistance, but also measuring the complex or reactive component in terms of a phase shift.

Existing methods for measuring a complex impedance include the use of a transimpedance amplifier. A transimpedance amplifier takes an input such as a very small current and provides a proportional output voltage. The transimpedance amplifier is frequently excited by an input sine wave, and the output is measured over sometimes a large number of cycles (such as hundreds or thousands of cycles). By measuring the voltage, the current, and the phase between the voltage and current, the total complex impedance can be calculated.

This method, however, has limitations in certain embedded or power constrained applications. Take, for example, the application of a blood glucose monitor. A blood glucose monitor may be required to continuously monitor a patient's blood glucose level. This can require taking, for example, one blood glucose sample every second. An example blood glucose monitor may use a potentiostat to measure blood glucose levels. The potentiostat works by attempting to maintain a constant voltage between a reference and a working electrode. An excitation current between the working electrode and a counter electrode is an output of a control loop, which tries to keep the potential between the reference electrode and working electrode constant. As the sensor is used over time, it may experience degradation, which can cause changes in the complex impedance between the working electrode and counter electrode. This includes a change in both resistance and capacitance. In general, the internal impedance of the counter electrode and the reference electrode can be representative of the overall health of the sensor. Thus, the health of the monitor can be observed by observing the change in complex impedance over time.

This application illustrates one of the limitations of the use of transimpedance amplifiers for impedance measurements. A transimpedance amplifier has a relatively high settling time. Because it uses a sinusoidal input that requires many samples to settle out, it may take a matter of tens or even hundreds of milliseconds for the transimpedance amplifier to settle before a sample can be taken. Once the transimpedance amplifier settles, a single sample is taken (or a handful of samples are taken to mitigate noise) and the sensor can then be shut down until the next sample. When it is time to take the next sample, the sensor reactivates, cycles through its settling time, and takes another sample or set of samples.

Another drawback of a transimpedance amplifier is that it requires a relatively high supply current. This can be a problem for very small (e.g., button) batteries, where even a few microamps can be considered a “very high” current draw for a discrete sample. In contrast, a current mirror may not require any substantial supply current at all. The current that must be supplied by the battery is proportional to the input current, which can be a very low current (on the order of nanoamps) for a very short time.

Consider an application where a blood glucose monitor is required to take one sample every minute, and it has a sampling time of 500 ms. Both of these example parameters are realistic in the existing art. In that case, the duty cycle of the blood glucose monitor is approximately 50%. Now assume that in operation, the monitor draws an average current of 1 mA. Each sample will then drain approximately 0.5 mA-seconds from the battery. This can make it necessary to use a larger battery to achieve the desired battery lifetime. This would lead to larger dimensions of a continuous glucose monitor, which becomes an inconvenience to the user, and in some cases may block acceptance of new technologies.

Thus, in battery-operated sensors, power consumption is a sometimes premium concern. To address this concern, the present specification provides an impedance measurement circuit in which linear amplifiers and a switched capacitor technique with a current mirror replace existing methods such as transimpedance amplifiers and sine wave excitation. This allows reduction of power consumption, while also increasing measurement speed. While the existing transimpedance-based measurement is power-hungry and can disturb the measurement itself, the technique disclosed herein uses very little power and does not disturb the measurement substantially. This means that more impedance samples can be taken, providing better (including more frequent) health monitoring for the transducer. This increases the confidence in the measured quantity itself (e.g., blood glucose level) because the health and reliability of the sensor are known.

The circuit disclosed herein excites the unknown impedance by an impulse rather than by a sine wave. A short series of impulses can be used to measure both the real and imaginary components of the load impedance. Thus, the settling time of the circuit disclosed herein may be orders of magnitude lower than in existing methods. Whereas a transimpedance amplifier-based solution may take hundreds of milliseconds to settle out in a blood glucose monitor, the circuit of the present specification may settle out in a period of a few microseconds. After this microseconds-long period, the impedance measurement circuit has an accurate measurement of both the resistive and reactive components of the load impedance.

Reduction of power consumption can be realized by using a step response instead of sinusoidal excitation for the impedance measurement circuit. Thus, both the duration of measurement and the number of samples taken can be significantly reduced. This results in power savings in the analog domain, as well as reduced processing effort in the digital domain.

To eliminate or reduce the input impedance of simpler current mirrors, a version of the circuit is described with a controlled bias voltage that delivers consistent results. The bias voltage of the current mirror input may be set to any value in order to control the voltage applied to the impedance under test.

The output of the current mirror can be connected to a capacitor to build an integrator. The integration time (tᵢₙₜ) may be set independently of the connection time to the impedance under test. The charge acquired by the capacitor may be transferred into a capacitive digital-to-analog converter (CAPDAC) of a successive approximation register analog-to-digital converter (SARADC). Alternately, the CAPDAC itself may be used to sample the charge directly, or the CAPDAC may be connected to an integration capacitor. It is also possible to have more than one integration capacitor. These can be binary weighted (as in a digital-to-analog converter) to provide a range of current to prevent capacitors from saturating. Integration capacitance can be adjusted to get the correct values. For example, it may be beneficial to have the highest resolution at the upper third of the desired range. The digital output of the SARADC is proportional to the charge of the integration capacitor (I×tᵢₙₜ).

In embodiments of the circuit described herein, DC decoupling capacitors (to decouple the H-bridge from sensor terminals) may be provided. This ensures that large or dangerous currents (including DC currents lumped with the AC measurement) are not injected into the body, which is mandated by law in some jurisdictions. Stray DC currents may also interfere with the impedance measurement.

To provide a precise measurement of the input current, a calibration with a known current may be performed before or after a measurement. This allows for limitations, such as imprecise capacitors and current mirrors. Offset errors and low-frequency noise can be reduced because they occur within the calibrated circuit.

The circuit described herein treats the measured signal as linear. For small changes with a limited demand for precision, the measurement process and the required calculations may be kept simple to save power. Note, however, that while a simple linear embodiment is disclosed herein as an illustrative example, the principles taught in this specification are equally applicable to more sophisticated signal capturing and processing circuits.

The output of the current mirror is usually not perfectly linear. A remedy for that would be a series of measurements that, through a control loop in the microcontroller (μC), would maintain the highest values of the voltage across the integration capacitor in the upper portion of the full-scale range before final conversions are taken through the analog-to-digital converter (ADC). That would result in usage of the current mirror in a smaller region with better linear behavior. It would also utilize the ADC as efficiently as possible, resulting in the lowest possible conversion noise for a given ADC resolution.

An advantage of the circuit disclosed herein is the ability to measure the charge that is stored in the series capacitor of the unknown impedance. A known amount of charge and the related voltage change (V_{diff}) allows calculation of the capacitance very easily (C=Q×V_{diff}). The internal voltage can be measured when the series resistance is known. The series resistance can be derived from a third stage of the measurement cycle (t2-t3). If the third stage takes twice as long as the second stage, the average voltage across the series capacitance equals V₀, which represents the voltage across the series capacitance before the first voltage step (Vₛₜₑₚ) is applied to the unknown impedance. This means that the resulting current is caused only by this series resistance. The series resistance can be calculated by R=Vₛₜₑₚ×tᵢₙₜ/Q. The series capacitance (i.e., the reactive component) can be calculated by relating the voltage difference (V_{diff}) of the interval t1-t2 and t3-t4. The voltage across the series resistance Rs is V=Rs× Q/tᵢₙₜ. Because the composition of impedances may be very different, the measurement range may be set appropriately by choosing correct timing, the voltage step, the size of tᵢₙₜ, and/or the transfer ratio of the current mirror. This may be achieved, for example, by knowing the character of the impedance to a certain extent or a success of the approximation scheme. Varying the timing for this same impedance under test may allow the capture of an impedance spectrum.

These teachings are useful in many different applications. As discussed above, a wearable blood glucose monitor may be required to operate essentially continuously, taking one or a plurality of samples every second. Thus, it is advantageous to have a much lower duty cycle for these types of circuits, thus drawing less power from the limited battery. Similarly, many smart watches exist that monitor a user's heart rate. Currently, the heart rate is measured using a photodiode that detects blood pulses. But heart rate can also be measured by minute changes in body impedance. The impedance measurement circuit of the present specification can take hundreds or thousands of samples per second because of its very low settling time. Thus, the user's heart rate may be determined by measuring the body impedance at a rate of kilo samples per second, and calculating the heart rate based on changes in impedance (e.g., driven by expansion of the blood vessels thus slightly changing the ratio of fat to electrolyte).

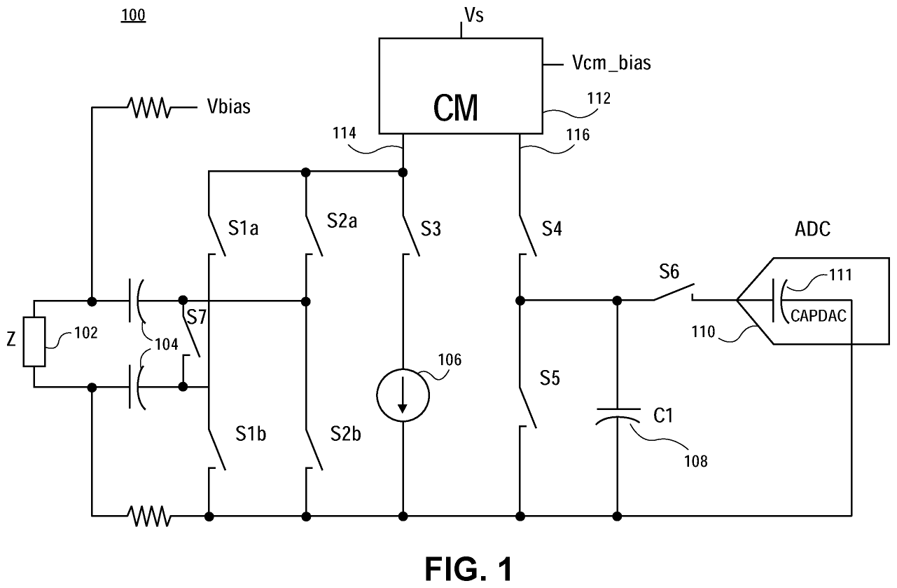

FIG. 1 is a schematic diagram of an example impedance measurement circuit 100, according to the teachings of the present specification. The impedance measurement circuit 100 is illustrated as including an unknown impedance Z 102 connected to the input, though it is understood that the impedance Z 102 is present during sensor operation. Impedance 102 can include a resistance and a capacitance in series, as well as a parallel resistance. The impedance measurement circuit 100 also includes a current source 106. Current source 106 can be electrically connected to a first electrical path 114 of a current mirror 112 through a switch S3.

The impedance measurement circuit 100 also includes a means for collecting charge 108, which can be a capacitor C1. The means for collecting charge 108 can be electrically connected to a second electrical path 116 of the current mirror 112 through a switch S4. The means for collecting charge 108 can be coupled to ground through a switch S5. The means for collecting charge 108 can also be electrically connected to an analog-to-digital (ADC) 110 through a switch S6. The ADC 110 can include a capacitive digital-to-analog converter circuit (e.g., IC or circuit element) (CAPDAC) 111.

The current mirror 112 can be coupled to the impedance 102 through a set of switches and circuit pathways that allow current to flow through the impedance 102 in a first direction and in a second direction. For example, current can flow between the impedance 102 and the current mirror 112 in a first direction when switches S1b and S2a are closed. As another example, current can flow between the impedance 102 and the current mirror 112 in a second direction when switches S1a and S2b are closed. Switches S1a, S1b, S2a, and S2b can be part of an H-bridge, which can be considered an electronic circuit that allows for a voltage to be applied across the impedance Z 102 in opposite directions or polarities.

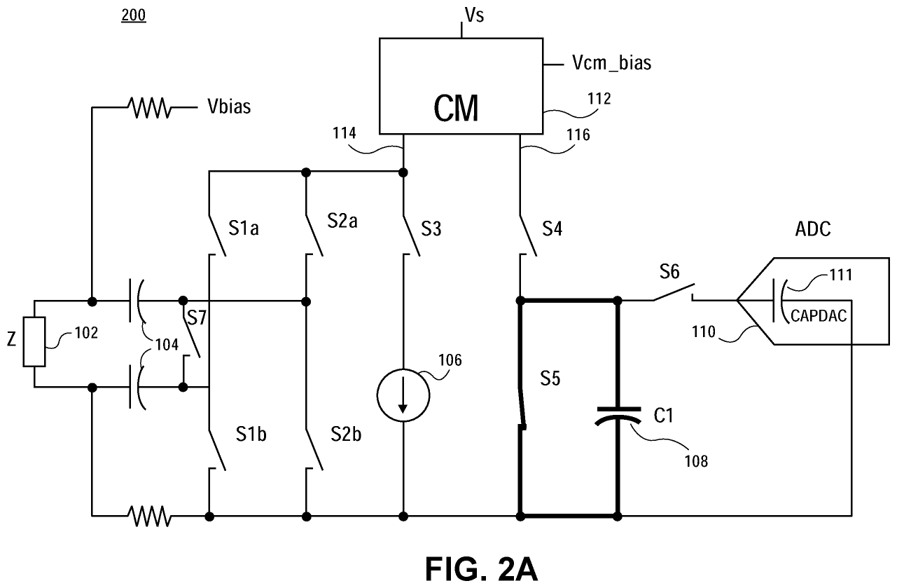

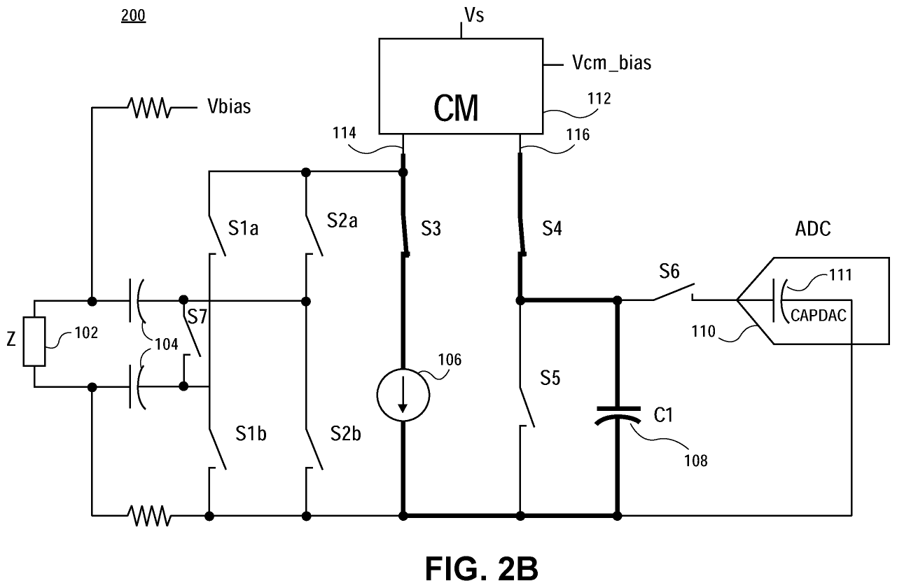

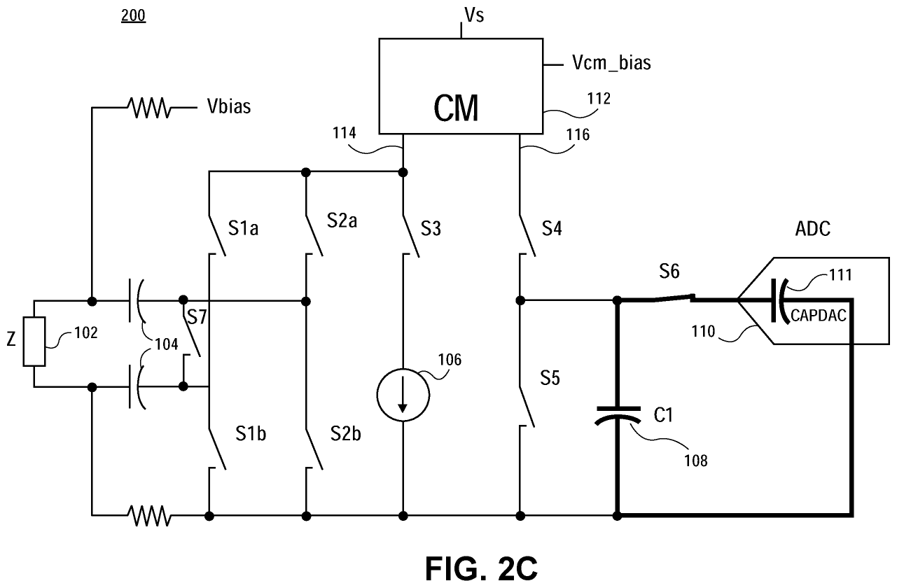

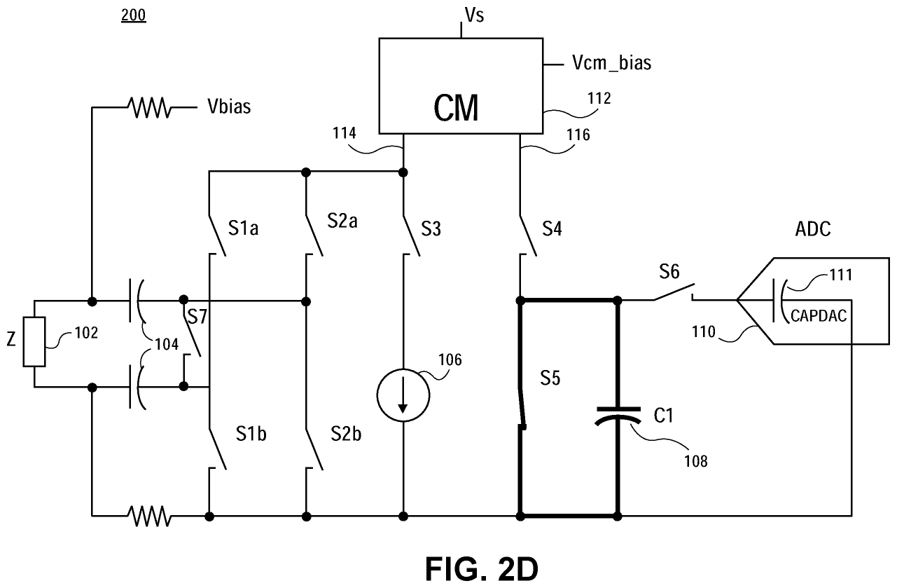

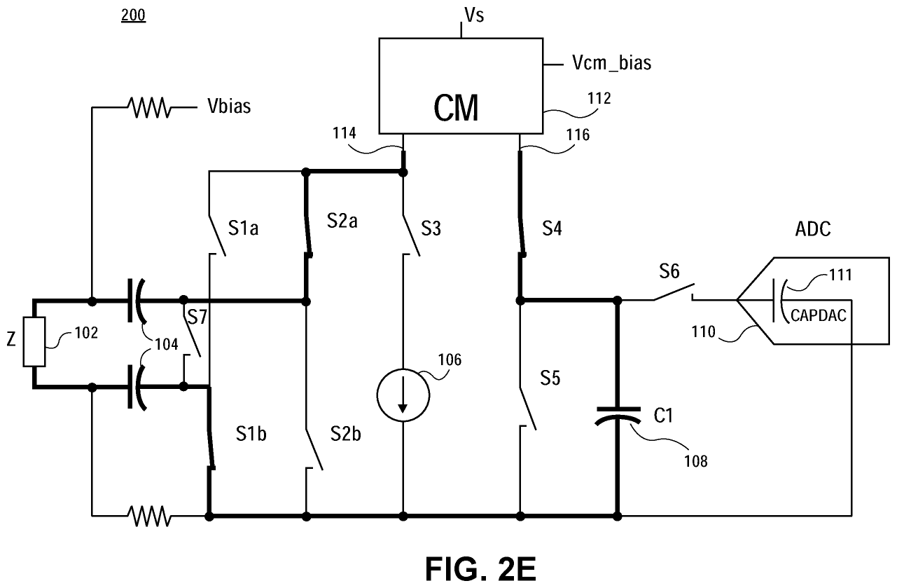

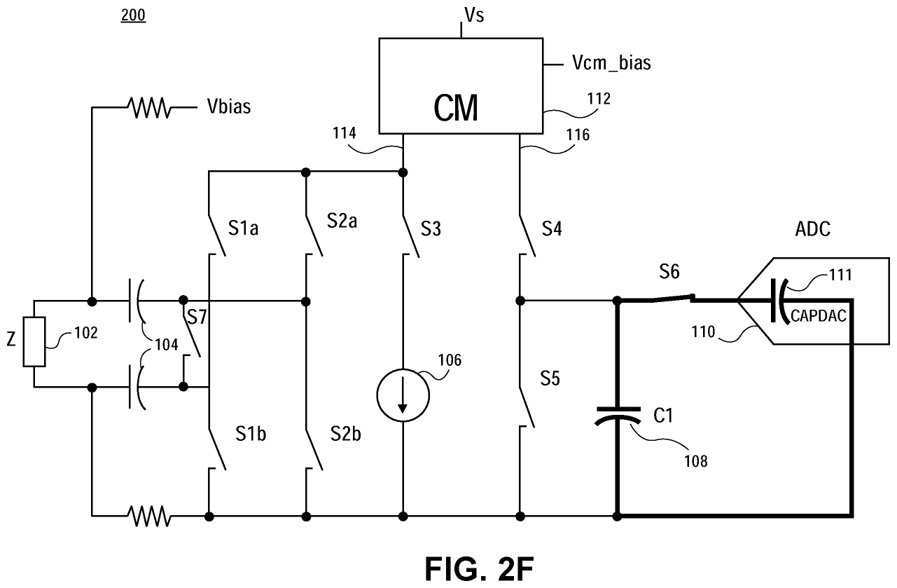

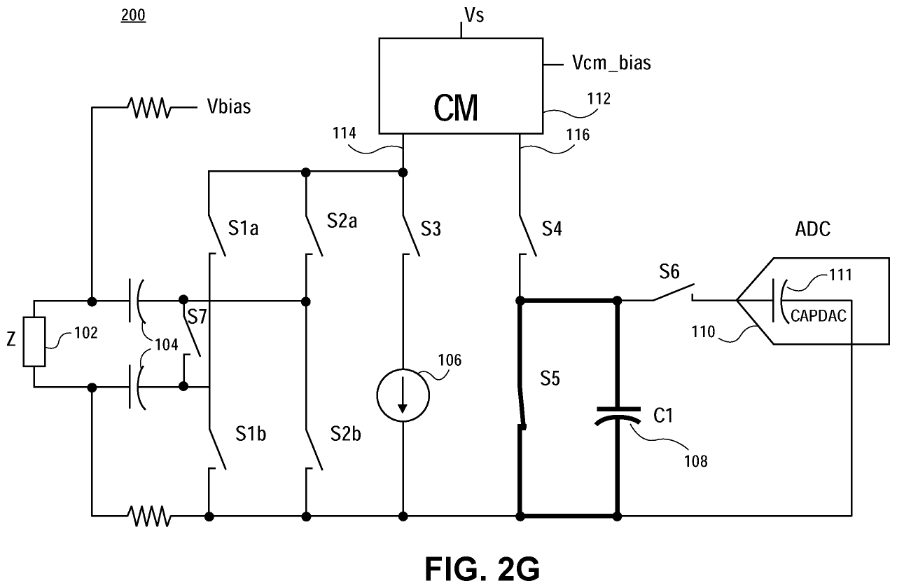

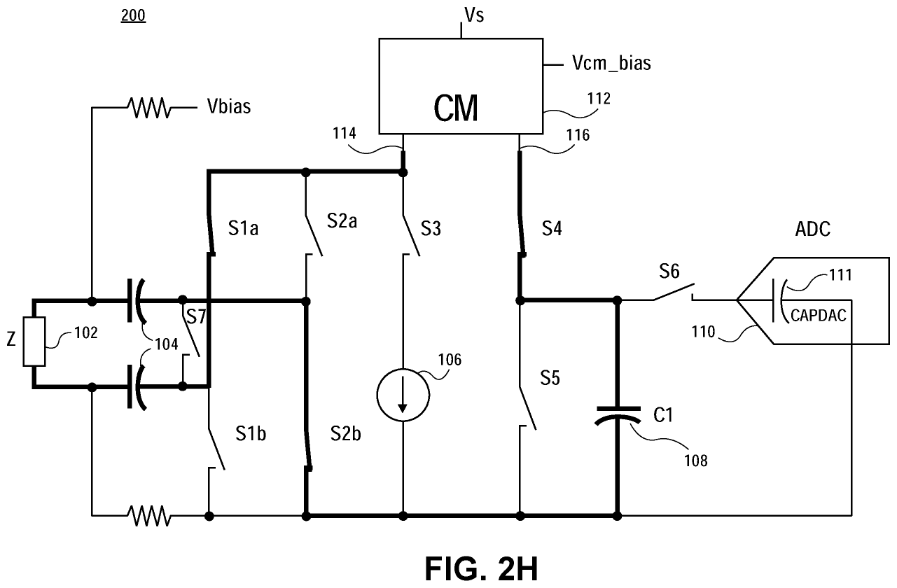

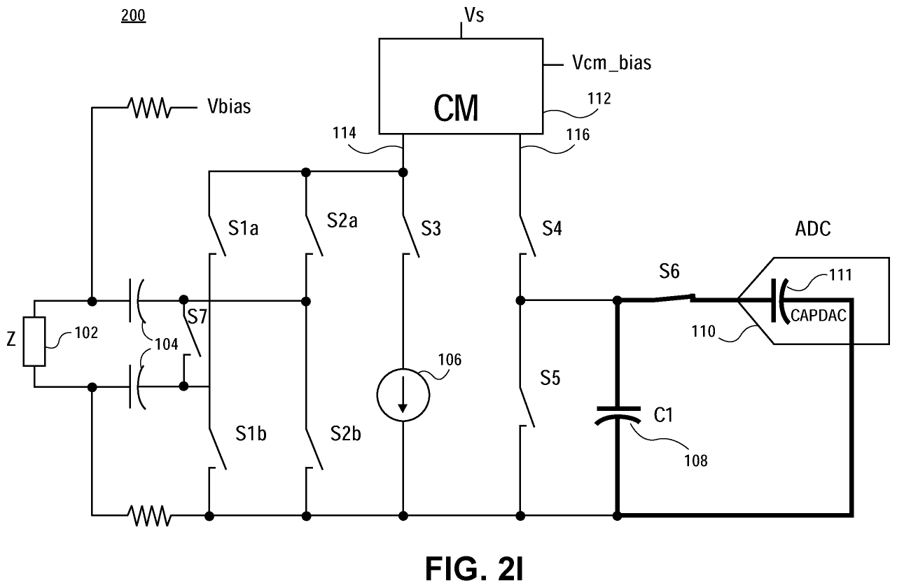

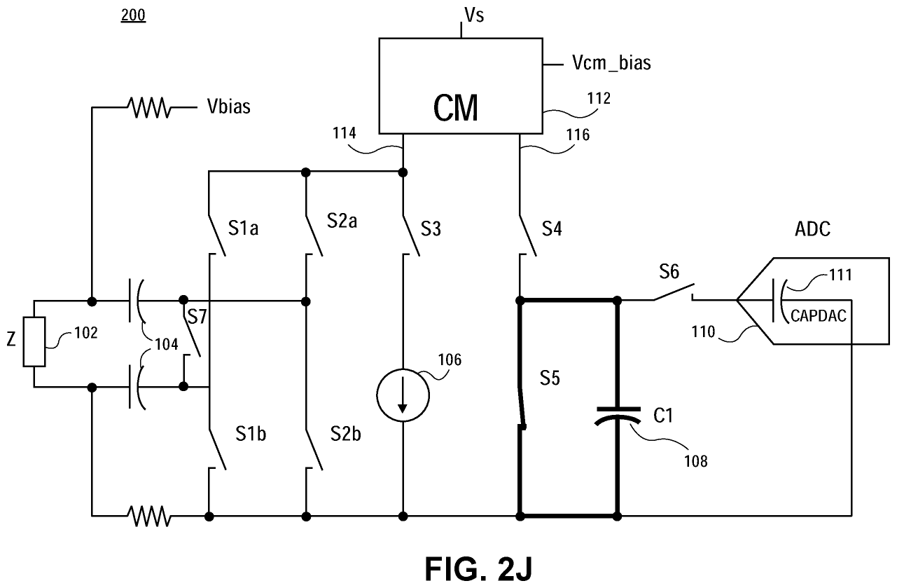

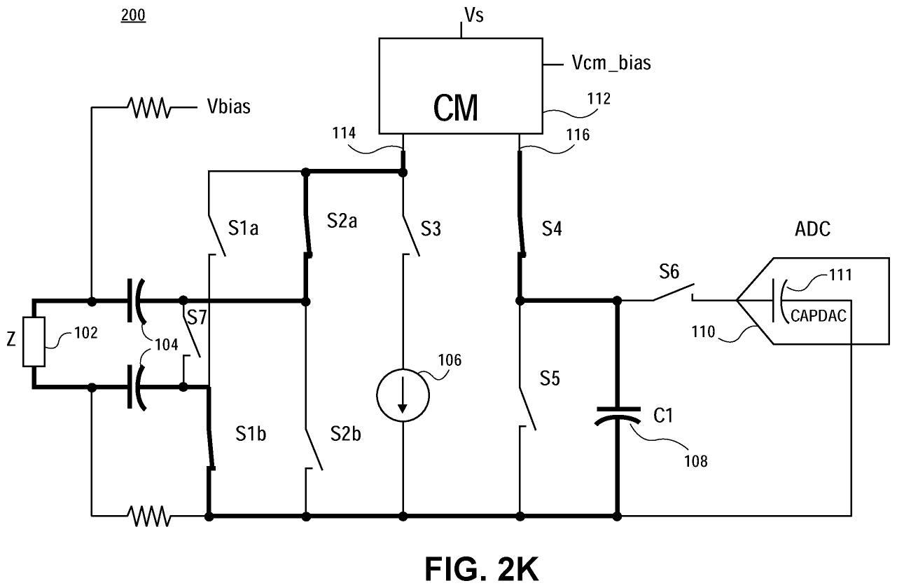

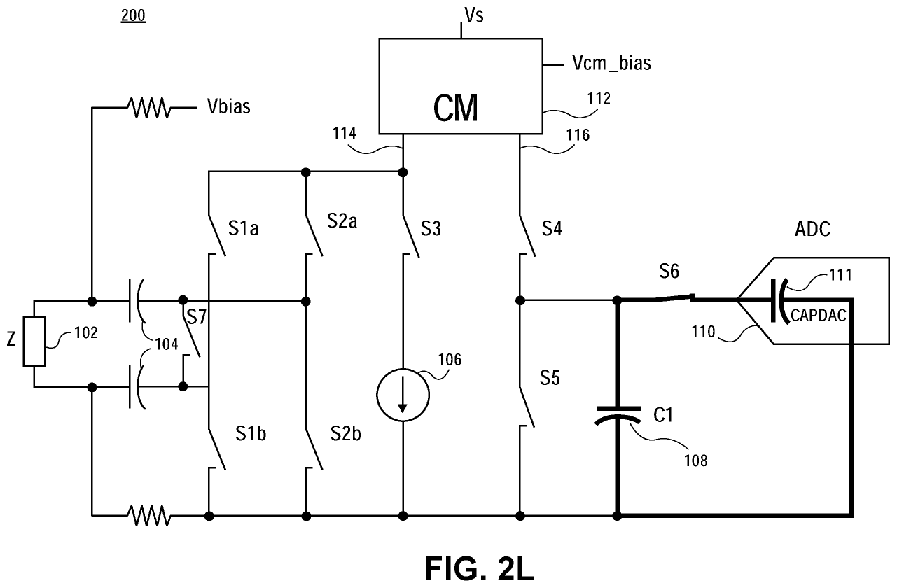

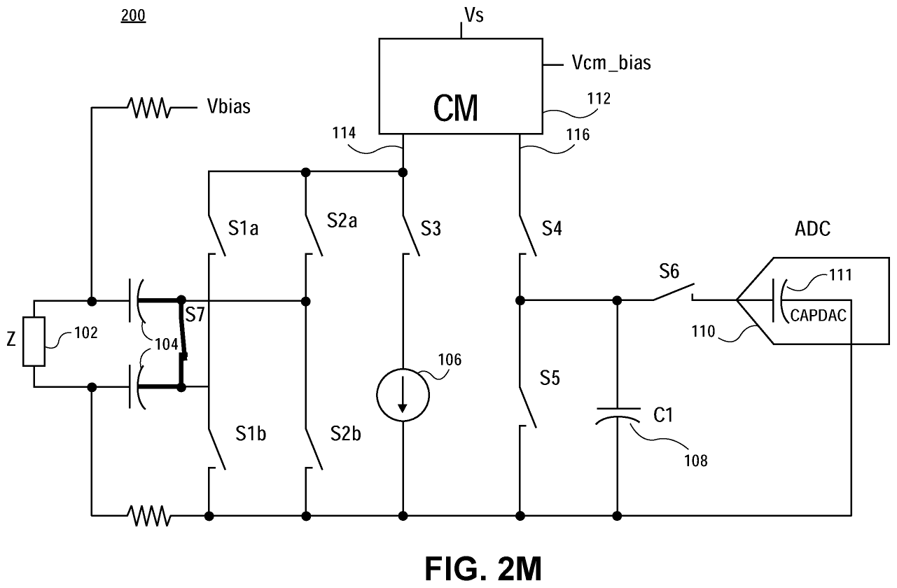

The switches S1-S6 can be timing-controlled, or can be controlled by other techniques, such as by voltages or by software. Operation of the impedance measurement circuit 100 is summarized in the text accompanying FIGS. 2A-2L.

Current mirror 112 can be a circuit designed to copy (or mirror) a current through one active device by controlling the current in another active device of a circuit, keeping the output current constant regardless of loading. The current mirror 112 can be characterized by a transfer ratio (among other characteristics), which scales or factors one current by a scaling factor. The scaling factor can be a value above zero.

In order to mitigate the input impedance of the current mirror 112, a bias voltage Vcm_{bias} can be applied to deliver more consistent results. The bias voltage Vcm_{bias} of the current mirror 112 can be set to any value in order to control the voltage applied to the impedance under test (e.g., impedance 102). The sequence of measurement steps (illustrated in FIGS. 2A-2L) show an AC coupled setup as it is used in DC biased electrochemical sensors, such as those used for continuous glucose measurement (CGM). The impedance measurement circuit 100 is capable of measuring a directly connected impedance under test (e.g., impedance 102).

An output (e.g., second electrical path 116) of the current mirror 112 can be connected to a means for collecting charge 108 (e.g., capacitor C1) across a switch S4 to act as an integrator. The integration time (tᵢₙₜ) can be set independently of the connection time to the impedance under test. This enables mitigation of effects caused by switching actions such as charge injection.

The charge acquired by the means for collecting charge 108 is then transferred into the CAPDAC of the ADC, which can be a success approximation register ADC (SARADC), by opening switch S4 and closing switch S6. The digital output of the ADC is proportional to the charge of the integration capacitor (capacitor C1) by I×tᵢₙₜ.

To allow AC coupling, a DC decoupler 104 allows applying both positive and negative polarities to the impedance under test (e.g., impedance 102). The DC decoupler 104 can include capacitors in series to impedance 102 on both ends, as shown in FIG. 1. DC decoupler 104 can be placed into a known state by closing either switches S1a and S2a, or S1b and S2b. But in some cases, this may introduce undesirable common-mode signals into the circuit. To avoid introducing an unwanted signal, switch S7 may be placed in parallel to the impedance 102 via capacitors 104. Closing switch S7 for a sufficient time restores capacitors 104 to a known (e.g., uncharged) state. Additional resistance in series with S7 may limit the discharge current through 102 to allowable values.

FIGS. 2A-2M are schematic diagrams illustrating operation of the example impedance measurement circuit of FIG. 1, according to the teachings of the present specification. In each of FIGS. 2A-2M, the bolded lines indicate a closed circuit path.

To facilitate precise measuring of the input current, a calibration with a known current is performed prior to or after an impedance measurement. The calibration procedure may be performed once for multiple consecutive measurements. FIGS. 2A-2D illustrate a calibration process. The calibration process allows the impedance circuit to work without precise knowledge of capacitor values and/or current mirror characteristics. Offset errors and low-frequency noise can be significantly reduced because they happen within the calibrated circuit. As an initial setting (as shown in FIG. 1), all switches are open and in an idle state for reference.

In FIG. 2A, the capacitor C1 is discharged by closing switch S5, which couples the capacitor C1 to ground. This step is performed to discharge the capacitor C1 of any residual charge.

In FIG. 2B, the current source 106 can be activated and coupled to a first electrical path 114 of the current mirror 112 by closing switch S3. The current mirror 112 outputs a mirrored current through the second electrical path 116 by opening switch S5 and closing switch S4. The capacitor C1 can collect charge Q for a predetermined amount of time.

In FIG. 2C, the switch S6 is closed (while other switches are opened) to discharge the capacitor into the ADC 110 (and CAPDAC 111). The ADC can output a digital value representative of the charge q collected on the capacitor C1.

In FIG. 2D, the switch S5 is opened again (while other switches are opened) to discharge the capacitor C1. The process of FIGS. 2A-2D (e.g., the calibration process) can be repeated for different amounts of charge collection times to gauge the non-linearity of the capacitor C1 and other circuit elements.

FIGS. 2E-2M illustrate an impedance measurement process. All switches are assumed to start in an idle (or open state).

In FIG. 2E, the switches S2a and S1b are closed to couple the first electrical path 114 of the current mirror to the impedance Z 102. The switch S4 is closed to couple the second electrical path 116 of the current mirror 112 to the capacitor C1. A known bias voltage V_{bias} is applied across the impedance. A known bias voltage Vcm_{bias} is also applied to the current mirror 112. In one example, the bias voltage Vcm_{bias} ranges from zero (or the most negative supply rail of the circuit) to the maximum voltage that the circuit can operate. This may operate on the assumption that the current mirror is tied to a positive supply voltage (using pFETs). A complementary setup is also possible, wherein the current mirror is tied to the negative rail (using nFETs). In that case, the range goes from the most positive supply rail to the most negative voltage that the current mirror can operate on.

The control voltage Vcm_{bias} sets the operating voltage of the current mirror which is applied as a voltage step across the impedance Z 102 via the switches S1a, S1b, S2a and S2b. The DC decoupler 104 can decouple any DC components of the bias voltage Vcm_{bias}. The effect of the capacitors for the DC decoupler 104 on the voltage across the impedance Z 102 is illustrated.

Another bias voltage V_{bias} can be applied to provide a DC offset. V_{bias} need only be constant during measurement procedures. For generic impedance measurements, there need be no external bias voltage at all (e.g., in a skin impedance measurement).

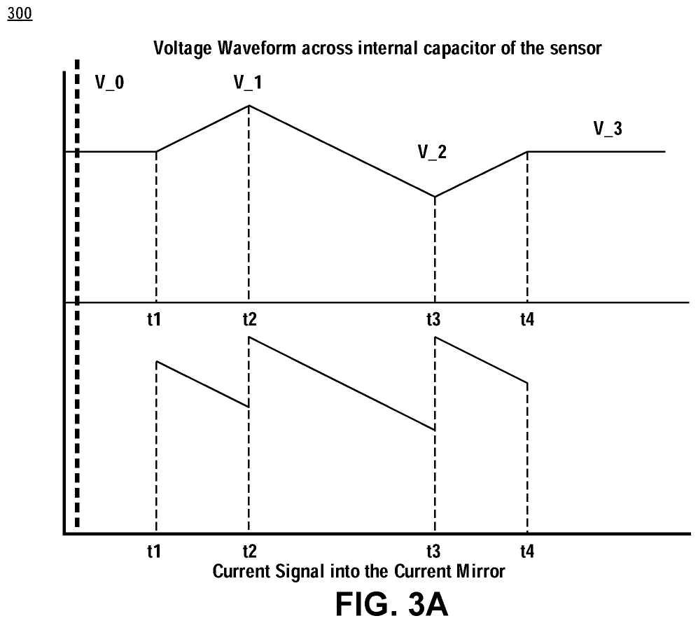

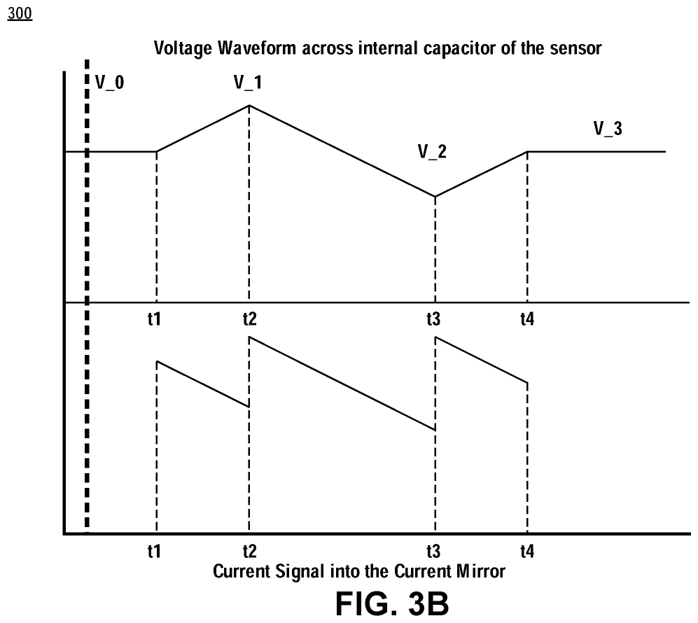

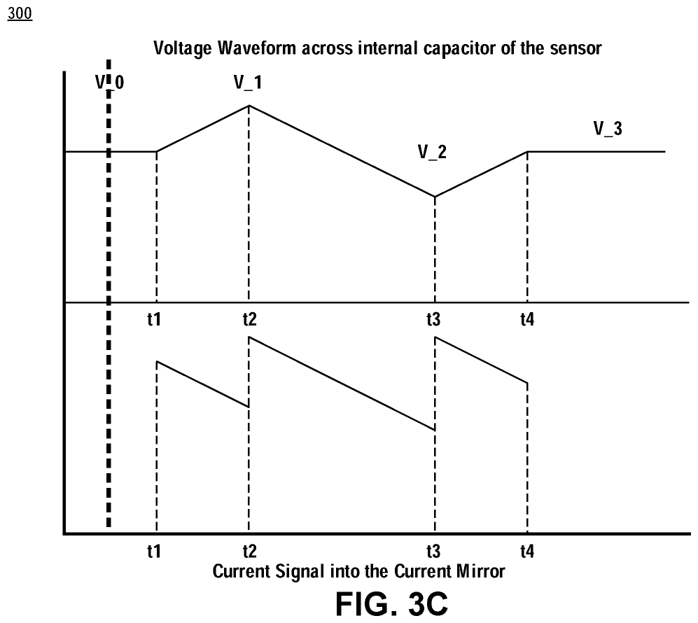

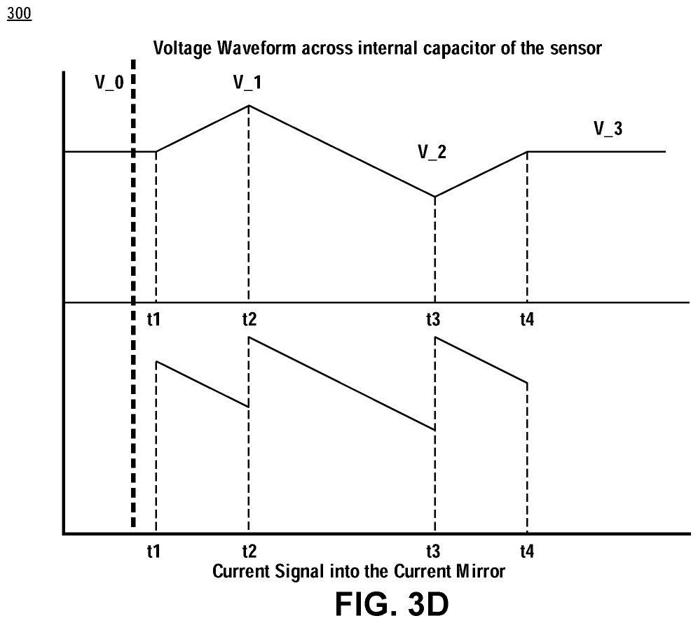

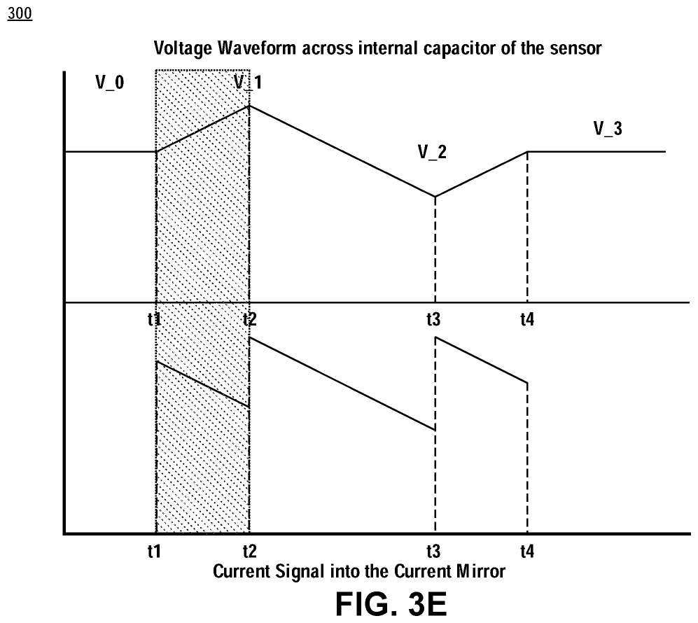

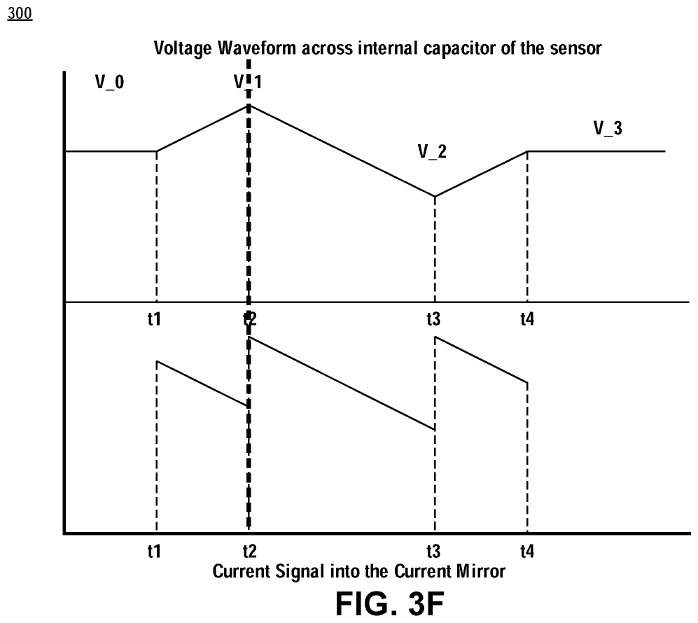

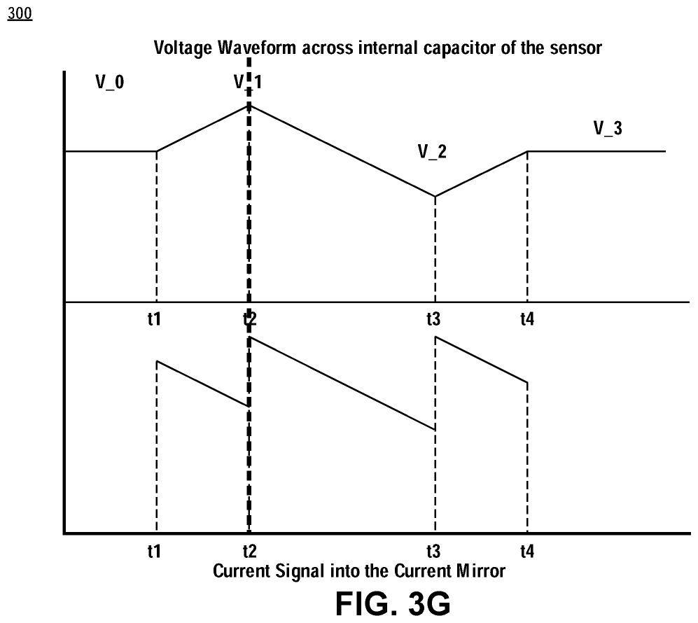

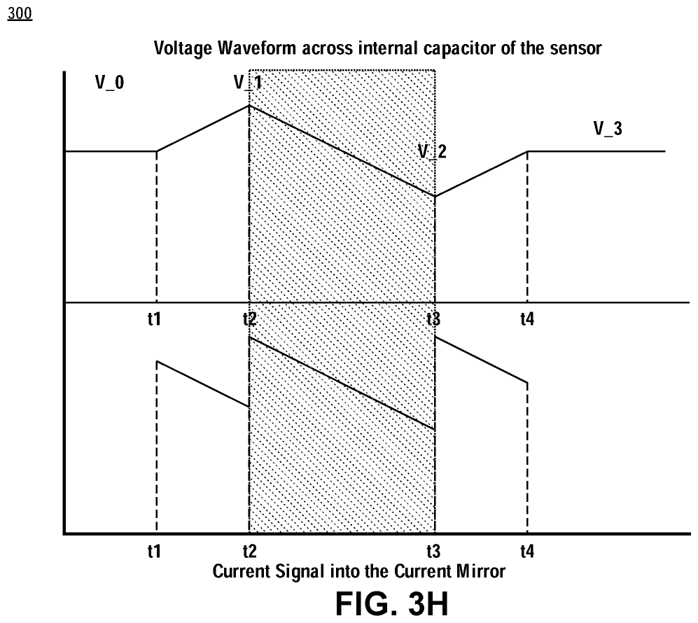

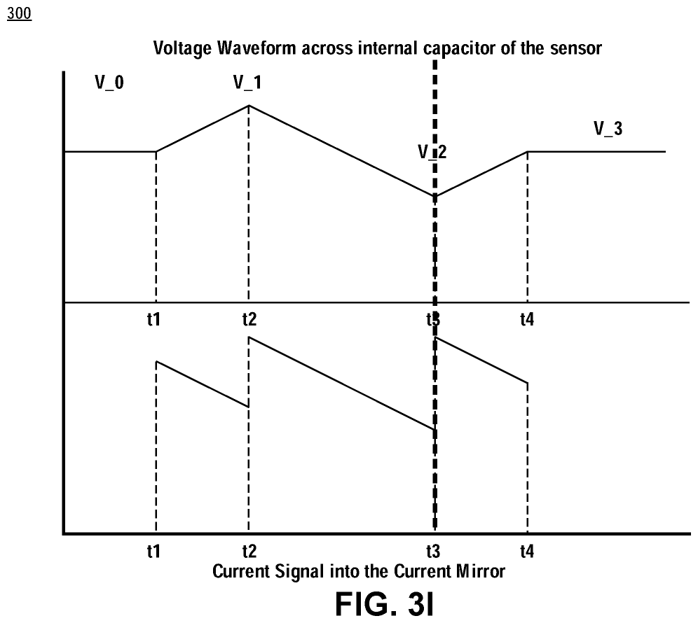

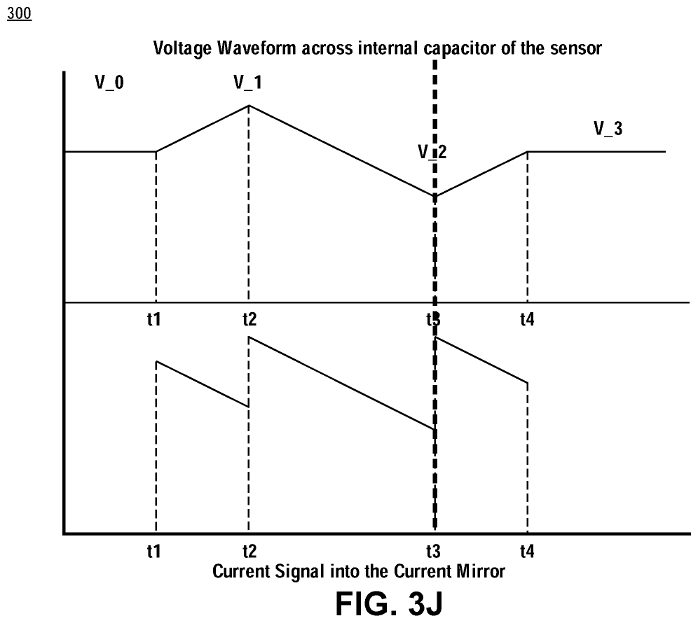

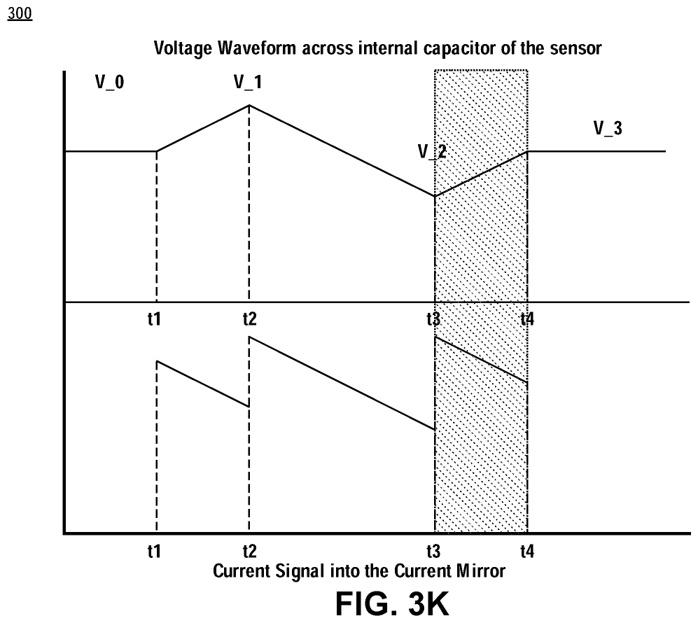

FIGS. 3A-3K are graphical representations of electrical responses for operating the impedance measurement circuit of FIG. 1, according to the teachings of the present specification.

In FIGS. 3A-3D, the voltage waveform across the capacitor in the impedance 102 is only seen as the DC offset caused by the bias voltage V_{bias}. FIGS. 3A-3D correspond to electrical response seen during the calibration steps described with FIGS. 2A-2D.

In FIG. 3E, the time t1 is the start time for the impedance measurement for impedance Z 102. The voltage starts at the DC offset value V₀, rising between time t1 to time t2, increasing in voltage to V₁ across the series capacitor of impedance Z 102. The increase in voltage across the capacitor in the impedance Z 102 corresponds to a decrease in current through a resistor in series with the capacitor, both of which make up the impedance Z 102. The decrease in current through the series resistor corresponds to a decrease in current reflected by the current mirror into the capacitor C1. Over a known amount of time t2-t1, an amount of charge q is built up on the capacitor C1.

Turning to FIG. 2F, the switches S2a and S1b are open, and the switch S6 is closed to discharge the capacitor C1 into the ADC 112. The ADC 112 can provide a digital value representative of the amount of charge Q1 collected between t1 and t2.

In FIG. 2G, the switch S6 is open and switch S5 is closed, which resets the capacitor C1 by coupling capacitor C1 to ground.

FIGS. 3F-3G illustrate the change in electrical response during the read-out steps and reset steps shown in FIGS. 2F-G.

In FIG. 2H, the polarity of the voltage (a Vcm_{bias} set value) applied across impedance Z 102 is reversed. This can be achieved by closing switch S1a and S2b to couple the impedance to the current mirror 112, and by closing switch S4 to couple the capacitor C1 to the second electrical path 116 of the current mirror 112. As shown in FIG. 3H, this contributes to the charge on the DC decoupler 104, as well as to the bias voltages V_{bias} and Vcm_{bias}. The voltage waveform across the series capacitor of impedance Z1 is shown to discharge from time t2 to t3, which is twice as long as the interval between t1 and t2. The decrease in current over time across the series resistor of the impedance Z 102 is reflected as a decrease in current into the current mirror 112, and charge collected over time t2-t3 at capacitor C1.

In FIG. 2I, the capacitor C1 is discharged by closing switch S6 (and opening all other switches) into the ADC, and a digital value is provided by the ADC corresponding to the charge Q2 collected by C1 from t2 to t3.

In FIG. 2J, switch S6 is open and switch S5 is closed, which resets the capacitor C1 by coupling capacitor C1 to ground.

FIGS. 3I and 3J reflect electronic response during the read-out and reset processes of FIGS. 2I and 2J, respectively.

In FIG. 2K, the switches S2a and S1b are closed to couple the first electrical path 114 of the current mirror to the impedance Z 102. The switch S4 is closed to couple the second electrical path 116 of the current mirror 112 to the capacitor C1. A charge Q3 is collected on capacitor C1 in a similar way as described above for FIG. 2E. FIG. 3K illustrates the electrical response. The voltage waveform across the internal series capacitor in the impedance Z 102 from time interval t3 to t4 has a lower median value than for the time period t1 to t2 due to the reversing of the voltage polarity from FIG. 2H.

In FIG. 2L, the capacitor C1 is discharged into the ADC by opening all switches. In FIG. 2M, switch S7 is closed, thus closing the circuit path.

An advantage of this impedance measurement circuit 102 is the ability to measure the charge that is stored in the series capacitance of the unknown impedance. A known amount of charge and the related change of the voltage (V_{diff}) between times t1 to t2 and times t3 to t4 allows for the calculation of the series capacitance of the impedance Z 102 by C=Q/V_{diff}.

The voltage of the internal node (e.g., a series RC in parallel with a resistance) can be measured when the series resistance of the impedance Z 102 is known. The series resistance of the impedance Z 102 can be derived from the third stage (i.e., FIG. 2H and FIG. 3H, from t2 to t3) of the measurement cycle. If t3-t2 is twice as long as t2-t1, the average voltage across the series capacitance of the impedance Z 102 equals V₀, which represents the voltage across the series capacitance of the impedance Z 102 prior to the first voltage step (Vₛₜₑₚ) applied to the unknown impedance. This means that the resulting current is caused only by the series resistance. The series resistance (Rs) of the impedance Z 102 can be calculated by Rs=Vₛₜₑₚ×tᵢₙₜ/Q.

The series capacitance of the impedance Z 102 can be calculated by relating the voltage difference (V_{diff}) between t1 to t2 and from t3 to t4. The actual voltage across Rs is V=Rs×Q/tᵢₙₜ.

Because the composition of impedances can vary, the measurement range is set appropriately by choosing the right timing for opening and closing switches S1-S6, the applied voltage step, the size of capacitor C1, and/or the transfer ratio of the current mirror. This can be achieved by knowing the character of the impedance to a certain extent or a successive approximation scheme. Varying the timing for the same impedance Z 102 can allow for the capture of an impedance spectrum.

The preceding technique is based on treating the measured signals as linear. For small changes and a limited demand for precision, the measurement process and the required calculations can be kept simple in order to save power. However, more sophisticated signal capturing and processing is possible.

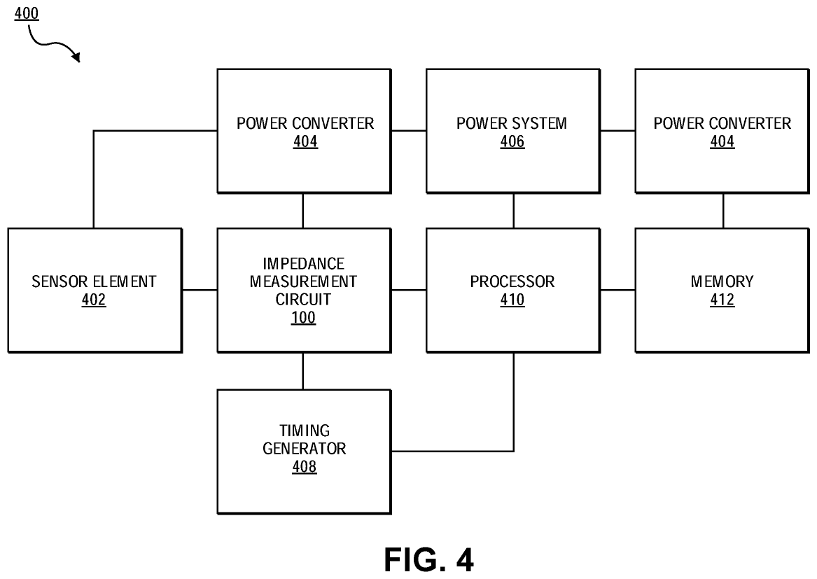

FIG. 4 is a schematic block diagram illustrating an example sensor system that incorporates the impedance measurement circuit of FIG. 1, according to the teachings of the present specification. The example sensor system 400 can be a battery-powered sensor, such as a portable or wearable sensor system. The sensor system 400 can be a sensor for measuring biopotentials, electrochemical reactions, or other electric measurements, including continuous glucose measurements (CGM). The sensor system 400 includes the impedance measurement circuit 100, as shown in FIG. 1, or a variation thereof. The impedance measurement circuit 100 can be coupled to a sensor element 402. The sensor element 402 can include two or more terminals, probes, nodes, etc., that interface with a sensor target. The sensor system 400 can include a power system 406, which can include a battery. The power system 406 can be coupled to a power converter 404. The power converter 404 can convert power from the power system 406 into the appropriate electrical signals for the sensor element 402, the processor 410, memory, and/or other components of the sensor system 400. The power converter 404 can supply bias voltage V_{bias}, current mirror voltage source Vs, current mirror bias voltage Vcm_{bias}, power for the ADC, as well as other electrical signals for the impedance measurement circuit.

The power system 406 can be controlled by a processor 410. The processor 410 can be a hardware processor and can include software. The processor 410 can access memory 412, which can store information, including sensor information, digital values representing charge, circuit component value information for the impedance measurement circuit 100, and programming for calculating impedance using stored values. The memory 412 can also store software associated with the sensor system 400. The sensor system 400 can include a timing generator for controlling the impedance measurement circuit 100 (such as the switches S1-S6). The processor 410 can control the timing generator 408 to open and/or close switches with the correct timing to capture sufficient charge to determine impedance values.

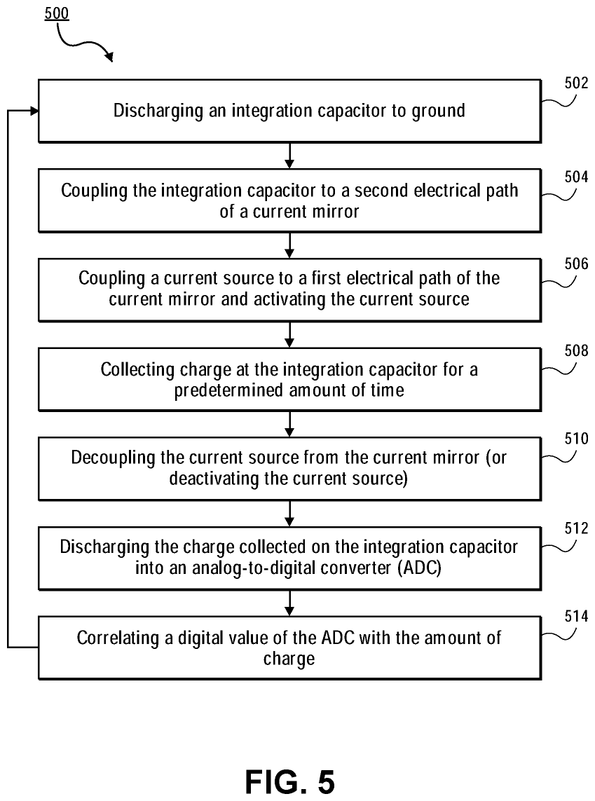

FIG. 5 is a process flow diagram for calibrating the impedance measurement circuit of FIG. 1, according to the teachings of the present specification. At the outset, an integration capacitor can be reset by coupling the integration capacitor to ground (502). The integration capacitor can be coupled to a second electrical path of a current mirror (504). A current source can be coupled to a first electrical path of the current mirror, activating the current source (506). The current mirror provides a current to the integration capacitor. The capacitor collects charge for one or more predetermined amounts of time (508). The current source can be decoupled from the current mirror (and/or can be deactivated) (510). The integration capacitor can be coupled to an analog-to-digital converter (ADC) to discharge the collected charge (512). The ADC, which can include a CAPDAC, can correlate the charge collected on the integration capacitor with a digital value (514). The calibration process can return to (502) to repeat the calibration process using different predetermined charge collection times to gauge linearity of the system.

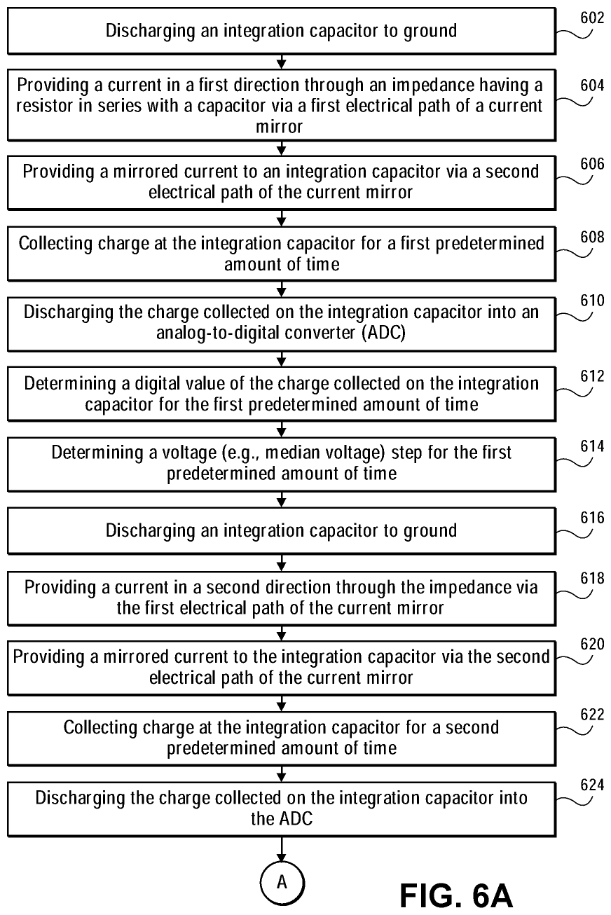

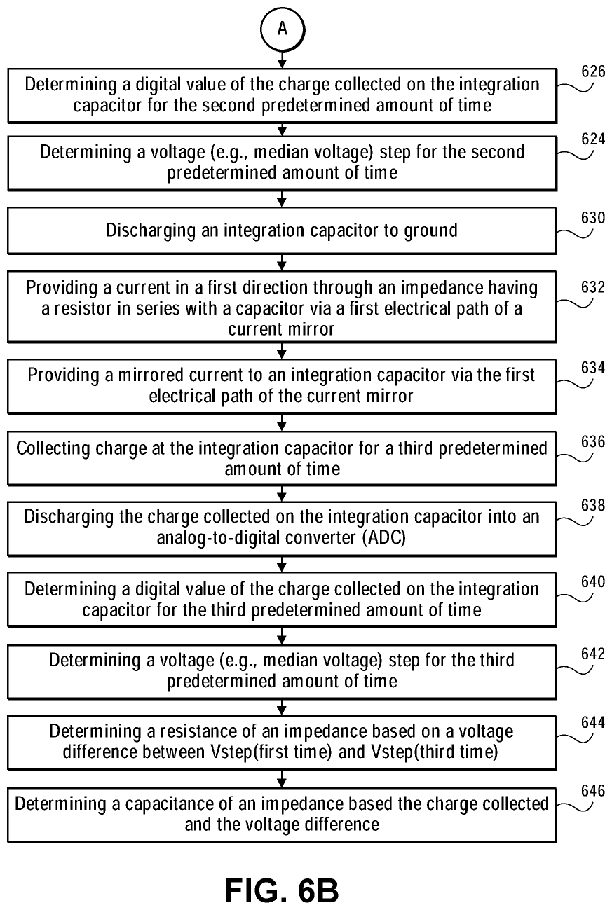

FIGS. 6A and 6B are a process flow diagram illustrating performing impedance measurement using the example circuit of FIG. 1, according to the teachings of the present specification. At the outset, the integration capacitor can be discharged (or reset) by coupling the integration capacitor to ground (602). A current can be provided in a first direction through a directly connected impedance having a resistor in series with a capacitor via a first electrical path of a current mirror (604). The current mirror can provide a mirrored current to an integration capacitor via a second electrical path of the current mirror (606). The integration capacitor can collect charge during an interval lasting from t1 to t2 (with duration t2-t1). The integration capacitor collects charge Q(t2-t1) for a first predetermined amount of time (e.g., t2-t1) (608). The collected charge Q(t2-t1) can be discharged into the CAPDAC of the ADC (610). ADC 610 can determine and/or provide a digital value of the charge collected on the integration capacitor for the first predetermined amount of time (612). A voltage step (e.g., median voltage) can be determined for the first predetermined amount of time (614). The integration capacitor can be coupled to ground to discharge (or reset) the integration capacitor (616).

A current can be provided in a second direction through the impedance via the first electrical path of the current mirror (618). The current mirror can provide a mirrored current to the integration capacitor via the second electrical path of the current mirror (620). Charge Q(t3-t2) can be collected at the integration capacitor for a second predetermined amount of time (t3-t2) (622). The charge Q(t3-t2) collected in the integration capacitor can be discharged into the ADC (624). A digital value of the charge Q(t3-t2) collected on the integration capacitor for the second predetermined amount of time can be determined (626). A voltage step (e.g., median voltage) for the second predetermined amount of time can be determined (628).

The integration capacitor can be coupled to ground to discharge (or reset) the integration capacitor (630).

A current can be provided in the first direction through an impedance having a resistor in series with a capacitor via a first electrical path of a current mirror (632). A mirrored current can be provided to an integration capacitor via the first electrical path of the current mirror (634). Charge Q(t4-t3) can be collected at the integration capacitor for a third predetermined amount of time (t4-t3) (636). The charge Q(t4-t3) collected on the integration capacitor can be discharged into an analog-to-digital converter (ADC) (638). A digital value of the charge Q(t4-t3) can be provided on the integration capacitor for the third predetermined amount of time (t4-t3) (640). A voltage step (e.g., median voltage) can be provided for the third predetermined amount of time (t4-t3) (642).

A series resistance of and impedance can be determined based on a voltage difference between Vₛₜₑₚ (first time) and Vₛₜₑₚ (third time) (644). A series capacitance of the impedance can be determined based the charge collected and the voltage difference V_{diff} (646).

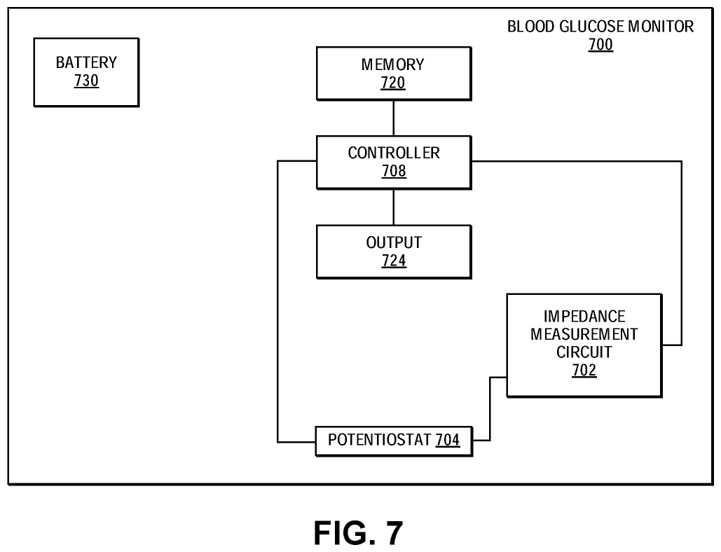

FIG. 7 is a block diagram of a blood glucose monitor 700, illustrating an application of the teachings of the present specification. Blood glucose monitor 700 may be, for example, a continuous and noninvasive blood glucose monitor. Numerous techniques for blood glucose monitoring have been investigated in the past 15 to 20 years. One particularly useful method is potentiostat-based measurement. In this case, a potentiostat as described above may be used to measure blood glucose level. As illustrated here, potentiostat 704 may be used to measure blood glucose levels at one or more samples per second. Impedance measurement circuit may be used to monitor the health of the potentiostat, such as by regularly sampling the complex impedance between the working electrode and the counting electrode (or by measuring the internal impedance of either or both electrode). This increases confidence in the quality of the reading.

This kind of continuous blood glucose monitor is particularly useful in so-called “telemedicine” applications, which continuously monitor a patient's health and provide diagnostic data, telemetry data, and prognoses. For example, controller 708 may store glucose measurements in memory 720, which may include both volatile (stored only while a device is powered) and nonvolatile (long-term and persistent) memories.

Embodiments of the teachings herein may be provided on a contemporary hardware computing platform. The hardware platform may be a single computing device (e.g., a dedicated server or appliance with a dedicated, on-board processor or processors, memory, storage, and peripherals). In other cases, the hardware platform may be more exotic. For example, in a large data center such as may be provided by a cloud service provider (CSP), the hardware platform may include rackmount servers with compute resources such as processors, memory, storage pools, accelerators, and other similar resources.

As used herein, a processor may include any programmable logic device with an instruction set. Processors may be real or virtualized, local or remote, or in any other configuration. A processor may be provided, by way of nonlimiting example, by Intel® (e.g., Xeon®, Core™, Pentium®, Atom®, Celeron®, x86, or others), Advanced Micro Devices (e.g., Kx-series x86 workalikes, or Athlon, Opteron, or Epyc-series Xeon workalikes), Advanced RISC Machines (ARM), and IBM (e.g., PowerPC and Power ISA processors), to name just a few.

In contemporary usage, “cloud computing” includes network-connected computing resources and technology that enables ubiquitous (often worldwide) access to data, resources, and/or technology. Cloud resources are generally characterized by great flexibility to dynamically assign resources according to current workloads and needs. This can be accomplished, for example, via virtualization, wherein resources such as hardware, storage, and networks are provided to a virtual machine (VM) via a software abstraction layer, and/or containerization, wherein instances of network functions are provided in “containers” that are separated from one another, but that share an underlying operating system, memory, and/or driver resources.

Interconnect technologies that may be found in embodiments of the present specification include, by way of nonlimiting example, silicon photonics (wherein silicon is used as an optical medium), a network interface card (NIC), an intelligent NIC (iNIC), a smart NIC, a home control assistant (HCA) or other home automation application, a peripheral component interconnect (PCI) or PCI express (PCIe), an UltraPath Interconnect by Intel®, an Intel® Omni-Path™ Architecture (OPA), an Infinity Fabric interconnect architecture by Advanced Micro Devices, Inc. (AMD), FibreChannel, Ethernet, FibreChannel over Ethernet (FCoE), InfiniBand, a legacy interconnect such as a local area network (LAN), a token ring network, a synchronous optical network (SONET), an asynchronous transfer mode (ATM) network, a wireless network such as Wi-Fi or Bluetooth, a “plain old telephone system” (POTS) interconnect or similar, a multi-drop bus, a mesh interconnect, a point-to-point interconnect, a serial interconnect, a parallel bus, a coherent (e.g., cache coherent) bus, a layered protocol architecture, a differential bus, or a Gunning transceiver logic (GTL) bus, to name just a few. The fabric may be cache and memory coherent, cache and memory non-coherent, or a hybrid of coherent and non-coherent interconnects.

As used in the present specification, a cache coherent memory architecture is one that provides uniform sharing and mapping between a plurality of caches. For example, the caches may map to the same address space. If two different caches have cached the same address in the shared address space, a coherency agent provides logic (hardware and/or software) to ensure the compatibility and uniformity of the shared resource. For example, if two caches have cached the same address, when the value stored in that address is updated in one cache, the coherency agent ensures that the change is propagated to the other cache. Coherency may be maintained, for example, via “snooping,” wherein each cache monitors the address lines of each other cache, and detects updates. Cache coherency may also be maintained via a directory-based system, in which shared data are placed in a shared directory that maintains coherency. Some distributed shared memory architectures may also provide coherency, for example by emulating the foregoing mechanisms.

Coherency may be either “snoopy” or directory-based. In snoopy protocols, coherency may be maintained via write-invalidate, wherein a first cache that snoops a write to the same address in a second cache invalidates its own copy. This forces a read from memory if a program tries to read the value from the first cache. Alternatively, in write-update, a first cache snoops a write to a second cache, and a cache controller (which may include a coherency agent) copies the data out and updates the copy in the first cache.

By way of nonlimiting example, current cache coherency models include MSI (modified, shared, invalid), MESI (modified, exclusive, shared, invalid), MOSI (modified, owned, shared, invalid), MOESI (modified, owned, exclusive, shared, invalid), MERSI (modified, exclusive, read-only or recent, shared, invalid), MESIF (modified, exclusive, shared, invalid, forward), write-once, Synapse, Berkeley, Firefly, and Dragon protocols. Furthermore, ARM processors may use advanced microcontroller bus architecture (AMBA), including AMBA 4 ACE, to provide cache coherency in systems-on-a-chip (SoCs) or elsewhere.

Some interconnects are more popular for certain purposes or functions than others, and selecting an appropriate interconnect for a particular application is an exercise of ordinary skill. For example, OPA and Infiniband are commonly used in high performance computing (HPC) applications, while Ethernet and FibreChannel are more popular in cloud data centers. But these examples are expressly nonlimiting, and as data centers evolve, interconnect technologies similarly evolve.

Note that while high-end interconnects such as OPA are provided herein by way of illustration, more generally, suitable interconnects may vary by particular application. These could, in some cases, include legacy interconnects like LANs, token ring networks, synchronous optical networks (SONET), ATM networks, wireless networks such as Wi-Fi and Bluetooth, POTS interconnects, or similar. It is also expressly anticipated that in the future, new network technologies may arise to supplement or replace some of those listed here.

Controller 708 may also output values according to output 724. For example, output 724 may provide a Bluetooth, Wi-Fi, radio frequency (RF), infrared, or other wired or wireless communication medium for transmitting results to an outside node. Output 724 could also include a display element that allows a user to view glucose values or trends. This can include, for example, a touchscreen or other display mechanism. Output 724 may also include things such as a speaker to provide audible alerts if blood glucose levels are above or below a certain value, or other useful information that may be of interest to the patient.

An important consideration for a blood glucose monitor such as blood glucose monitor 700 is that it may be designed to be portable, convenient, and consistent. Part of the utility of blood glucose monitor 700 is that it provides continuous data for the user, to provide real-time health monitoring in a noninvasive manner. One factor in ease and reliability is the life cycle of battery 730. For purposes of this illustration, it can be assumed that battery 730 provides all primary power to blood glucose monitor 700. As long as battery 730 remains charged, blood glucose monitor 700 can continue operating. Once battery 730 becomes discharged, blood glucose monitor 700 may cease to operate until battery 730 is replaced or recharged. To encourage adoption of blood glucose monitor 700, it is desirable to have a battery 730 that lasts as long as possible.

As discussed above, known impedance measurement circuits that rely on transimpedance amplifiers have relatively large settling times. This means that, taking for example a single sample per second, the duty cycle of impedance measurement circuit 702 may be as high as 50%. This provides a substantial drain on battery 730, and thus requires the user to replace or recharge the battery more frequently. This can become an annoyance to the user, and may cause the user to seek alternative solutions, such as lancet-based blood glucose testing, or a noninvasive blood glucose monitor from another vendor that requires less charging.

However, the impedance measurement circuit of the present specification has a substantially lower settling time than a transimpedance amplifier-based impedance measurement circuit. Impedance measurement circuit 702 may be an embodiment, for example, of the circuit of FIG. 1 or any of the FIG. 2 herein. As discussed earlier, embodiments of the disclosed circuit have a settling time in the range of microseconds versus a range of milliseconds for transimpedance amplifier-based impedance measurement circuits. Because impedance measurement circuit 702 has a very low duty cycle, it can take, for example, one sample every second and still draw very little power from battery 730. Indeed, the current draw of an impedance measurement circuit 702 may be on the order of picoamps on average, and thus may actually be less than the internal leakage current of battery 730.

While elements such as controller 708 and output 724 will still draw more power, the substantial reduction in power draw by impedance measurement circuit 702 can translate into much longer battery life for blood glucose monitor 700. This means that a user of blood glucose monitor 700 may be able to use the device for one to several weeks without having to recharge or replace the battery, thus making adoption far more likely. Not only is this more convenient for the user, but also results in better overall healthcare results for patients. Because continuous data can be not only be shown to the user, but also shared (utilizing appropriate privacy controls) with healthcare providers and others who have a legitimate interest in the data, better treatment regimens can be crafted for users of such devices. These enhanced treatment options can also be propagated out to provide benefits to others in the larger healthcare community with similar conditions.

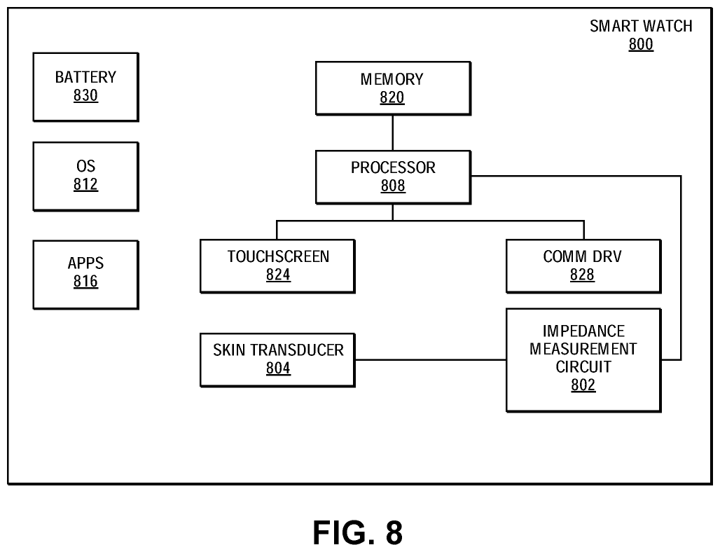

FIG. 8 is a block diagram of a smart watch 800, illustrating a further application of the teachings of the present specification. Similar to blood glucose monitor 700 of FIG. 7, smart watch 800 may include an embodiment of impedance measurement circuit 802.

One of the common uses of smart watches is as telemetric health devices. These may not be as specific as a blood glucose monitor, but rather may monitor broader health state indicators such as heart rate, blood oxygen levels, perspiration, and other factors.

Considerations for smart watch 800 may be similar to considerations for blood glucose monitor 700. Smart watch 800 may need to be reliable and convenient to be broadly adopted by the community. As with blood glucose monitor 700, smart watch 800 faces one inherent limitation in battery 830. If battery 830 is drained, then smart watch 800 may cease to function until battery 830 has been recharged or replaced.

Smart watch 800 includes elements such as a processor 808 and a memory 820. It may communicate with a user via touchscreen 824, which may be for example a capacitive or resistive touchscreen that enables a user to interact with smart watch 800.

Smart watch 800 may also include a communication driver 828, which could be, for example, a Bluetooth, Wi-Fi, infrared, RF, or other wireless or wired communication interface.

Smart watch 800 may be a relatively sophisticated device, and may be limited largely not by its processing power, but rather by the size of touchscreen (or other human-machine interface) 824. Touchscreens for smart watches tend to be small, and thus have limited interaction space. However, smart watches can be provided with relatively powerful processors that would have been considered top-of-the-line only a few years ago, and with relatively capable memory that would have been considered “enough for anybody” in a previous generation. Thus, smart watch 800 may have an embedded operating system 812, such as an embedded Linux, Windows, Apple iOSx, VxWorks or any other real-time or embedded operating system. This also provides the ability for apps 816 to reside on smart watch 800. Apps 816 may provide a relatively rich user experience and sophisticated interaction with smart watch 800.

Many users employ their smart watches as health monitors to measure, for example, their heart rate, perspiration, steps taken, level of activity, and other factors. Taking heart rate as a particular example, many existing smart watches employ a photodiode which provides a pulse that reflects off of a blood vessel to measure heart rate. Such optical pulse measurement techniques suffer from a similar inherent limitation to the transimpedance amplifier-based impedance measurement circuit. These circuits may have relatively high duty cycles, and/or draw relatively high amounts of power from battery 830. It is therefore desirable to provide a skin transducer 804 that draws less power, and/or has a lower duty cycle. Skin transducer 804 may use impedance measurements of the body to detect or infer heart rate.

This skin transducer 804 has inherent advantages over existing heart rate monitors in that it draws very little power from battery 830. Again, the skin transducer 804 may have a duty cycle of only microseconds per second, and may draw an average power on the order of nanoamps.

Because skin transducer 804 has such a low settling time, it is possible to take on the order of kilo samples per second from skin transducer 804, still without having a large duty cycle. Taking such a large number of samples per second can provide a continuous heart rate profile of the user without resulting in substantial drain on battery 830. Thus, the design objective of long battery life, with large spans between having to recharge or replace battery 830, can be realized.

Various concepts may be embodied as at least one non-transitory computer readable storage medium (e.g., a computer memory, one or more floppy discs, compact discs, optical discs, magnetic tapes, flash memories, circuit configurations in field programmable gate arrays or other semiconductor devices, etc.) or a computer readable storage device (which may include the foregoing examples) encoded with one or more programs that, when executed on one or more computers or other processors, implement some of the various embodiments of the present application.

### Example Implementations

The following examples are provided by way of illustration.

There is disclosed in one example a circuit for measuring impedance, comprising: a current mirror comprising a first current path and a second current path; a sensor having a terminal electrically coupled to the first current path of the current mirror circuit; a charge collector electrically coupled to the second current path of the current mirror; and an analog-to-digital converter to output a digital value of charge on the charge collector over a known time, wherein the digital value corresponds to an impedance of the sensor.

There is further disclosed a circuit for measuring impedance, wherein the charge collector comprises a capacitor.

There is further disclosed a circuit for measuring impedance, further comprising: a first switch to electrically couple the charge collector to a ground; and a second switch to electrically couple the charge collector to the analog-to-digital converter.

There is further disclosed a circuit for measuring impedance, further comprising: a current source electrically connected to the first current path of the current mirror; a third switch to electrically couple the charge collector to the current mirror; and a fourth switch to electrically couple the current source to the current mirror.

There is further disclosed a circuit for measuring impedance, further comprising a current mirror bias voltage source electrically coupled to an input port of the current mirror.

There is further disclosed a circuit for measuring impedance, further comprising: an impedance circuit element electrically coupled to the sensor; and a voltage bias electrically coupled to the impedance circuit element.

There is further disclosed a circuit for measuring impedance, wherein the current mirror is configured to receive a current mirror bias voltage to provide a voltage step to the sensor terminal.

There is further disclosed a circuit for measuring impedance, further comprising an H-bridge, the H-bridge comprising a plurality of switches to reverse a polarity of a voltage across the terminal of the sensor.

There is further disclosed a circuit for measuring impedance, further comprising a timer to switch a plurality of switches according to a timing scheme, the timing scheme configured to cause the charge collector to collect charge over the known time.

There is further disclosed a circuit for measuring impedance, wherein the analog-to-digital converter comprises a capacitive digital-to-analog converter circuit element to convert charge discharged from the charge collector into a digital representation of the charge.

There is further disclosed a circuit for measuring impedance, further comprising a processor or microcontroller to determine an impedance across the sensor terminals based on charge collected by the charge collector.

There is further disclosed a circuit for measuring impedance, wherein the processor element is configured to determine impedance by determining a resistance based on the charge collected by the charge collector and a voltage step across the charge collector for the known time.

There is further disclosed a circuit for measuring impedance, wherein the processor element is configured to determine impedance by determining a capacitance based on the charge collected by the charge collector and a voltage difference of two voltage steps across the charge collector for two known times.

There is also disclosed a method for measuring impedance, comprising: providing a first current through an impedance at a sensor terminal in a first direction via a first electrical path of a current mirror for a first known time; providing a first mirrored current by a second electrical path of the current mirror to an integration capacitor for the first known time; discharging the capacitor into an analog-to-digital converter; determining a digital representation of a first collected charge on the integration capacitor over the first known time; determining a first voltage drop across the integration capacitor for the first known time; providing a second current through the impedance at the sensor terminal in a second direction via a first electrical path of the current mirror for a second known time, the second direction opposite the first direction; providing a second mirrored current by the second electrical path of the current mirror to the integration capacitor for the second known time; discharging the capacitor into the analog-to-digital converter; determining a digital representation of a second collected charge on the integration capacitor over the second known time; determining a second voltage drop across the integration capacitor for the second known time; providing a third current through the impedance at the sensor terminal in the first direction via the first electrical path of the current mirror for a third known time using a first voltage step value; providing a third mirrored current by the second electrical path of the current mirror to the integration capacitor for the third known time; discharging the capacitor into the analog-to-digital converter; determining a digital representation of a third collected charge on the integration capacitor for the third known time; determining a third voltage drop across the integration capacitor for the third known time; and determining a characteristic of the impedance based, at least in part, on the first voltage drop, the second voltage drop, the first collected charge, and the second collected charge.

There is further disclosed a method, wherein determining a characteristic of the impedance comprises determining a resistance of the impedance based on

$$R = \frac{( {V}_{s t e p} ) ( {t}_{int} )}{Q} ,$$

wherein R is the series resistance of the impedance, Vₛₜₑₚ is a voltage step applied to the impedance, tᵢₙₜ is a known time; and Q is a collected charge by the integration capacitor.

There is further disclosed a method, wherein determining a characteristic of the impedance comprises determining a capacitance of the impedance based on: C=Q/V_{diff}, wherein C is the series capacitance of the impedance, V_{diff} is a voltage drop difference between the first known time and second known time, and Q is a collected charge on the integration capacitor.

There is further disclosed a method, further comprising: prior to providing the first current through the impedance: discharging the integration capacitor to ground; providing a known calibration current for a calibration time period on the first electrical path of the current mirror; mirroring the known calibration current for the first time period on the second electrical path of the current mirror; collecting a calibration charge on the integration capacitor for the calibration time period; discharging the calibration charge into the analog-to-digital converter; and determining a digital value representative of the charge based on the known current and the calibration time period.

There is also disclosed a system comprising: a sensor element comprising two or more sensor terminals; a timing generator; a power source comprising a battery; an impedance measurement circuit, comprising: a current mirror circuit comprising a first current path and a second current path; an integration capacitor electrically connected to the second current path of the current mirror; and an analog-to-digital converter to output a digital representation of charge on the integration capacitor charge over a predetermined amount of time; the two or more sensor terminals electrically connected to a first current path of the current mirror; and a processor implemented at least partly in hardware to determine a charge on the integration capacitor based on the digital representation of charge and to determine an impedance across the two or more sensor terminals based, at least in part, on the determined charge on the integration capacitor.

There is further disclosed a system, further comprising an H-bridge electrically connected to the first current path of the current mirror, the H-bridge comprising a plurality of switches and configured to reverse a direction of current flow across the impedance.

There is further disclosed a system, wherein the processor is configured to determine the impedance based on

$$R = \frac{( {V}_{s t e p} ) ( {t}_{int} )}{Q} ,$$

wherein R is the series resistance of the impedance, Vₛₜₑₚ is a voltage step applied to the impedance, tᵢₙₜ is a known time; and Q is a collected charge by the integration capacitor.

There is also disclosed a blood glucose monitor comprising the system of a number of the above examples.

There is also disclosed a smart watch comprising the system of a number of the above examples.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

In the claims, as well as in the specification above, all transitional phrases such as “comprising,” “including,” “carrying,” “having,” “containing,” “involving,” “holding,” “composed of,” and the like are to be construed as open-ended, i.e., to mean including but not limited to. The transitional phrases “consisting of” and “consisting essentially of” shall be closed or semi-closed transitional phrases, respectively.

What is claimed is:

1. A circuit for measuring impedance, comprising:
a current mirror comprising a first current path and a second current path;
a sensor having a terminal electrically coupled to the first current path of the current mirror circuit;
a charge collector electrically coupled to the second current path of the current mirror; and
an analog-to-digital converter to output a digital value of charge on the charge collector over a known time, wherein the digital value corresponds to an impedance of the sensor.

2. The circuit for measuring impedance of claim 1, wherein the charge collector comprises a capacitive digital-to-analog converter (CAPDAC) in parallel with a capacitive integrator.

3. The circuit for measuring impedance of claim 1, further comprising:
a first switch to electrically couple the charge collector to a ground; and
a second switch to electrically couple the charge collector to the analog-to-digital converter.

4. The circuit for measuring impedance of claim 3, further comprising:
a current source electrically connected to the first current path of the current mirror;
a third switch to electrically couple the charge collector to the current mirror; and
a fourth switch to electrically couple the current source to the current mirror.

5. The circuit for measuring impedance of claim 1, further comprising a current mirror bias voltage source electrically coupled to an input port of the current mirror.

6. The circuit for measuring impedance of claim 1, further comprising:
an impedance circuit element electrically coupled to the sensor; and
a voltage bias electrically coupled to the impedance circuit element.

7. The circuit for measuring impedance of claim 1, wherein the current mirror is configured to receive a current mirror bias voltage to provide a voltage step to the sensor terminal.

8. The circuit for measuring impedance of claim 1, further comprising an H-bridge, the H-bridge comprising a plurality of switches to reverse a polarity of a voltage across the terminal of the sensor.

9. The circuit for measuring impedance of claim 1, further comprising a timer to switch a plurality of switches according to a timing scheme, the timing scheme configured to cause the charge collector to collect charge over the known time.

10. The circuit for measuring impedance of claim 1, wherein the analog-to-digital converter comprises a capacitive digital-to-analog converter circuit element to convert charge discharged from the charge collector into a digital representation of the charge.

11. The circuit for measuring impedance of claim 1, further comprising a processor, microcontroller, or state machine to determine an impedance across the sensor terminals based on charge collected by the charge collector.

12. The circuit for measuring impedance of claim 11, wherein the processor element is configured to determine impedance by determining a resistance based on the charge collected by the charge collector and a voltage step across the charge collector for the known time.

13. The circuit for measuring impedance of claim 11, wherein the processor element is configured to determine impedance by determining a capacitance based on the charge collected by the charge collector and a voltage difference of two voltage steps across the charge collector for two known times.

14. A method for measuring an impedance, comprising:
charging an integration capacitor through a current mirror via a current in a first direction for a first time;
computing a first voltage drop across the integration capacitor for the first time based on a first collected charge on the integration capacitor;
charging the integration capacitor through the current mirror via a current in a second direction for a second time;
computing a second voltage drop across the integration capacitor for the second time based on a second collected charge on the integration capacitor; and
computing a characteristic of the impedance based, at least in part, on the first voltage drop, the second voltage drop, the first collected charge, and the second collected charge.

15. The method of claim 14, further comprising computing the first collected charge and second collected charge on the integration capacitor, comprises discharging the integrating capacitor into a digital-to-analog converter to provide a digital representation of collected charge.

16. The method of claim 14, wherein determining a characteristic of the impedance comprises determining a series resistance R of the impedance based on a product of Vₛₜₑₚ and tᵢₙₜ, divided by Q, wherein Vₛₜₑₚ is a voltage step applied to the impedance, tᵢₙₜ is a known time; and Q is a collected charge by the integration capacitor.

17. The method of claim 14, wherein determining a characteristic of the impedance comprises determining a capacitance of the impedance based on: C=Q/V_{diff}, wherein C is the series capacitance of the impedance, V_{diff} is a voltage drop difference between the first known time and second known time, and Q is a collected charge on the integration capacitor.

18. The method of claim 14, further comprising:
prior to providing the first current through the impedance:
discharging the integration capacitor to ground;
providing a known calibration current for a calibration time period on the first electrical path of the current mirror;
mirroring the known calibration current for the first time period on the second electrical path of the current mirror;
collecting a calibration charge on the integration capacitor for the calibration time period;
discharging the calibration charge into the analog-to-digital converter; and
determining a digital value representative of the charge based on the known current and the calibration time period.

19. A system comprising:
a sensor element comprising two or more sensor terminals;
a timing generator;
a portable power source;
an impedance measurement circuit, comprising:
a current mirror circuit comprising a first current path and a second current path;
an integration capacitor electrically connected to the second current path of the current mirror; and
an analog-to-digital converter to output a digital representation of charge on the integration capacitor charge over a predetermined amount of time;
the two or more sensor terminals electrically connected to a first current path of the current mirror; and
a processor implemented at least partly in hardware to determine a charge on the integration capacitor based on the digital representation of charge and to determine an impedance across the two or more sensor terminals based, at least in part, on the determined charge on the integration capacitor.

20. The system of claim 19, wherein the processor is configured to determine the impedance based on
$$R = \frac{( {V}_{s t e p} ) ( {t}_{int} )}{Q} ,$$
wherein R is the series resistance of the impedance, Vₛₜₑₚ is a voltage step applied to the impedance, tᵢₙₜ is a known time; and Q is a collected charge by the integration capacitor.
